(19) United States
(12) Patent Application Publication
(10) Pub. No.: US 2025/0284369 A1
(43) Pub. Date: Sep. 11, 2025

(54) DISPLAY DEVICE AND ELECTRONIC PRODUCT

(71) Applicant: Samsung Display Co., Ltd., Yongin-si (KR)

(72) Inventors: Junhyeong Park, Yongin-si (KR); Jonghwa Park, Yongin-si (KR)

(21) Appl. No.: 19/071,666

(22) Filed: Mar. 5, 2025

(30) Foreign Application Priority Data
Mar. 6, 2024 (KR) 10-2024-0032223

(51) Int. Cl. G06F 3/044; H01L 25/075

(52) U.S. Cl. CPC G06F 3/0446; G06F 3/0443; G06F 3/0447; H01L 25/0753; G06F 2203/04102

(57) ABSTRACT

A display device includes a substrate, light-emitting elements above the substrate, and defining a display area capable of providing a three-dimensional image plane, a touch layer above the light-emitting elements, and including touch electrodes, strain sensors in the display area, and a touch detector electrically connected to the touch layer and to the strain sensors, and configured to sense a touch input based on a relationship between an elongation rate and capacitance of the display area.

### CROSS-REFERENCE TO RELATED APPLICATION

The present application claims priority to, and the benefit of, Korean Patent Application No. 10-2024-0032223, filed on Mar. 6, 2024, in the Korean Intellectual Property Office, the disclosure of which is incorporated by reference herein in its entirety.

### BACKGROUND

### 1. Field

One or more embodiments relate to a flexible display device and an electronic product.

### 2. Description of the Related Art

As display devices visually displaying electrical signals have developed, various display devices having excellent characteristics, such as thinness, light weight, and low power consumption, have been introduced. For example, flexible display devices that may be folded or rolled into a roll shape have been introduced. Recently, research into and development of display devices with various structures, such as stretchable display devices that may change into various shapes, have been actively conducted.

### SUMMARY

One or more embodiments include a display device, for example, a flexible display device and an electronic product.

Additional aspects will be set forth in part in the description which follows and, in part, will be apparent from the description, or may be learned by practice of the presented embodiments of the disclosure.

According to one or more embodiments, a display device includes a substrate, light-emitting elements above the substrate, and defining a display area capable of providing a three-dimensional image plane, a touch layer above the light-emitting elements, and including touch electrodes, strain sensors in the display area, and a touch detector electrically connected to the touch layer and to the strain sensors, and configured to sense a touch input based on a relationship between an elongation rate and capacitance of the display area.

The display area may include sub-areas, wherein the strain sensors are in respective ones of the sub-areas.

The touch detector may be configured to sense the touch input by comparing a measured elongation rate of the sub-areas and a measured capacitance of the touch electrodes corresponding to the sub-areas with reference data.

The touch detector may be configured to generate the reference data by setting a relationship between an elongation rate of the sub-areas and a capacitance of the touch electrodes corresponding to the sub-areas according to three-dimensional deformation of the display area.

The touch electrodes may include first touch electrodes arranged in a first direction and electrically connected to each other, and second touch electrodes arranged in a second direction crossing the first direction and electrically connected to each other.

Each of the sub-areas may correspond to a portion of two adjacent ones of the first touch electrodes and a portion of two adjacent ones of the second touch electrodes.

The touch electrodes may include a column of first touch electrodes arranged in a first direction, and a column of second touch electrodes arranged in the first direction and adjacent to the column of the first touch electrodes in a second direction.

The touch electrodes may include a column of first touch electrodes arranged in a first direction, and a second touch electrode adjacent to the column of the first touch electrodes in a second direction and extending in the first direction.

The strain sensors may include a serpentine conductive line.

The display area may include pixels corresponding to the light-emitting elements, wherein the serpentine conductive line has a mesh shape surrounding at least one of the pixels in plan view.

The display device may further include a protection layer above the light-emitting elements, wherein the strain sensors are between the protection layer and the touch layer.

According to one or more embodiments, a display device includes a substrate, light-emitting elements above the substrate, and defining a display area capable of providing a three-dimensional image plane, a touch layer above the light-emitting elements, and including touch electrodes, strain sensors in a non-display area outside the display area, and a touch detector electrically connected to the touch layer and the strain sensors, and configured to sense a touch input based on a relationship between an elongation rate and a capacitance of the display area.

The touch electrodes may include an alternating arrangement of a column of first touch electrodes arranged in a first direction, and at least one second touch electrode adjacent to the column of the first touch electrodes in a second direction, wherein the strain sensors include a Wheatstone bridge including a corresponding one of the first touch electrodes.

The display device may further include trace lines respectively connecting the strain sensors and the first touch electrodes, and passing through the display area.

The display area may include sub-areas, wherein the first touch electrodes are respectively arranged in the sub-areas, and wherein the touch detector is configured to sense the touch input by comparing a measured elongation rate of the sub-areas and a measured capacitance of the touch electrodes corresponding to the sub-areas with reference data.

The touch detector may be configured to generate the reference data by setting a relationship between an elongation rate of the sub-areas and a capacitance of the touch electrodes corresponding to the sub-areas according to three-dimensional deformation of the display area.

The touch electrodes may be arranged in the first direction and the second direction, and each of the strain sensors comprises a Wheatstone bridge comprising a corresponding one of the touch electrodes.

The display device may further include trace lines respectively connecting the strain sensors and the touch electrodes, and passing through the display area.

The display area may include sub-areas, wherein the touch electrodes are respectively arranged in the sub-areas, and wherein the touch detector is configured to sense the touch input by comparing a measured elongation rate of the sub-areas and a measured capacitance of the touch electrodes corresponding to the sub-areas with reference data.

The touch detector may be configured to generate the reference data by setting a relationship between an elongation rate of the sub-areas and a capacitance of the touch electrodes corresponding to the sub-areas according to three-dimensional deformation of the display area.

According to one or more embodiments, a display device includes a substrate, light-emitting elements above the substrate, and defining a display area capable of providing a three-dimensional image plane and including sub-areas, a touch layer above the light-emitting elements, and including touch electrodes, and a touch detector electrically connected to the touch layer, and configured to sense a touch input by comparing capacitance of one of the touch electrodes corresponding to the sub-areas and reference data with each other.

The touch detector may be configured to sense the capacitance by using a mutual capacitance method or a self-capacitance method.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic perspective view of a display device according to one or more embodiments;

FIGS. 2A and 2B are perspective views showing the display device of FIG. 1 stretched in a first direction;

FIG. 2C is a perspective view showing the display device of FIG. 1 stretched in a second direction;

FIG. 2D is a perspective view showing the display device of FIG. 1 stretched in the first direction and the second direction;

FIG. 2E is a perspective view showing the display device of FIG. 1 stretched in a third direction;

FIG. 3 is a schematic plan view of a display device according to one or more embodiments;

FIGS. 4A and 4B are plan views each showing an excerpt of a portion of a display area of a display device according to one or more embodiments;

FIG. 5 is a cross-sectional view of a portion of a display area of a display device according to one or more embodiments, taken along the line Va-Va′ and taken along the line Vb-Vb′ of FIG. 4A;

FIG. 6 is a schematic equivalent circuit diagram of a pixel circuit and a light-emitting diode of FIG. 5;

FIGS. 7A to 7D are schematic cross-sectional views of a light-emitting diode of a display device according to one or more embodiments;

FIG. 8 is a schematic plan view of a touch layer of a display device according to one or more embodiments;

FIG. 9 is an enlarged plan view of a region VIII of FIG. 8;

FIG. 10 is an enlarged plan view of part of a first touch electrode and a second touch electrode of a display device according to one or more embodiments;

FIG. 11 is a cross-sectional view of a touch layer, taken along the line XI-XI′ of FIG. 9;

FIG. 12A is a schematic plan view of an arrangement of strain sensors included in a display device according to one or more embodiments;

FIG. 12B is a plan view of a portion of any one strain sensor of FIG. 12A;

FIGS. 12C and 12D are enlarged plan views each showing a region XII of FIG. 12B;

FIGS. 13A to 13C are schematic cross-sectional views each showing a portion of a display device including a strain sensor;

FIG. 14 is a diagram of a display device according to one or more embodiments, mainly showing a touch electrode;

FIG. 15 is a perspective view showing a three-dimensional deformation state of a display device according to one or more embodiments;

FIG. 16 is a flowchart showing operations of a touch detector according to one or more embodiments;

FIG. 17A is a graph for visually explaining reference data for each sub-area, and FIG. 17B is a graph for visually explaining how a touch detector senses a touch input;

FIGS. 18A and 18B are schematic plan views each showing a touch layer of a display device according to one or more embodiments;

FIG. 19 is a cross-sectional view of a portion of the touch layer shown in FIGS. 18A and 18B;

FIGS. 20A and 20B are schematic plan views each showing touch electrodes and a sensor portion of a display device according to one or more embodiments;

FIG. 21 is a diagram of a display device according to one or more embodiments, mainly showing a touch electrode and a strain sensor;

FIG. 22 is a schematic plan view of touch electrodes and a sensor portion of a display device according to one or more embodiments;

FIG. 23 is a diagram of a display device according to one or more embodiments, mainly showing a touch electrode and a strain sensor;

FIGS. 24 and 25 are perspective views each showing an electronic product to which a display device has been applied, according to one or more embodiments;

FIGS. 26A to 26C are plan views each showing touch electrodes of a display device according to one or more embodiments;

FIG. 27 is a flowchart showing operations of a touch detector according to one or more embodiments; and

FIG. 28A is a graph for visually explaining reference data for each sub-area, and FIG. 28B is a graph for visually explaining how a touch detector senses a touch input.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

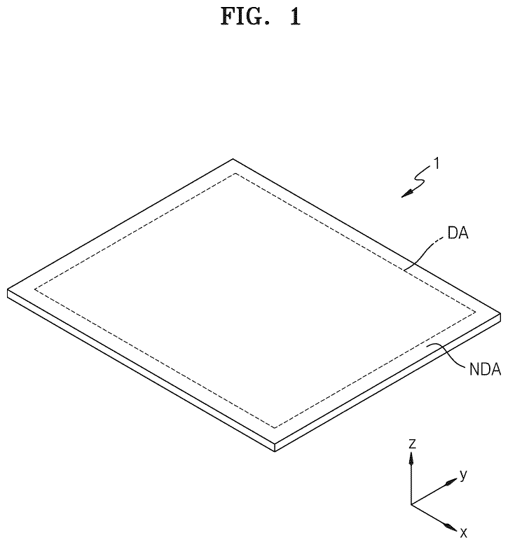

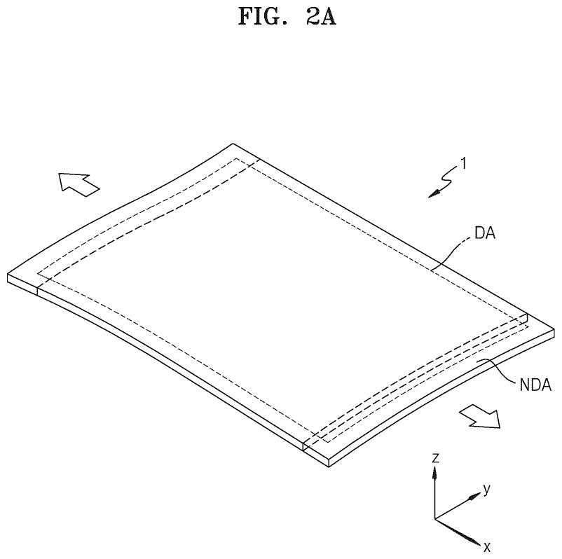

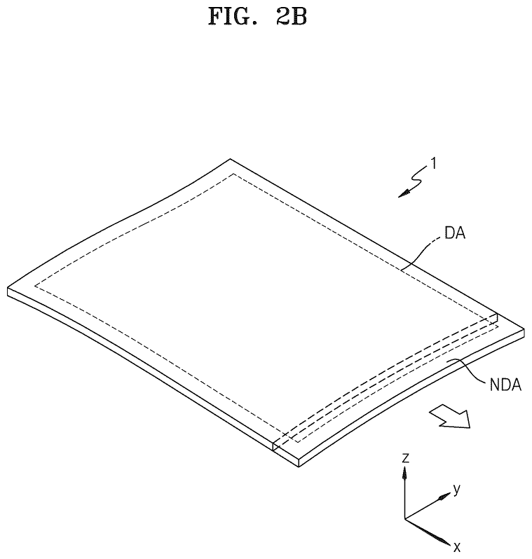

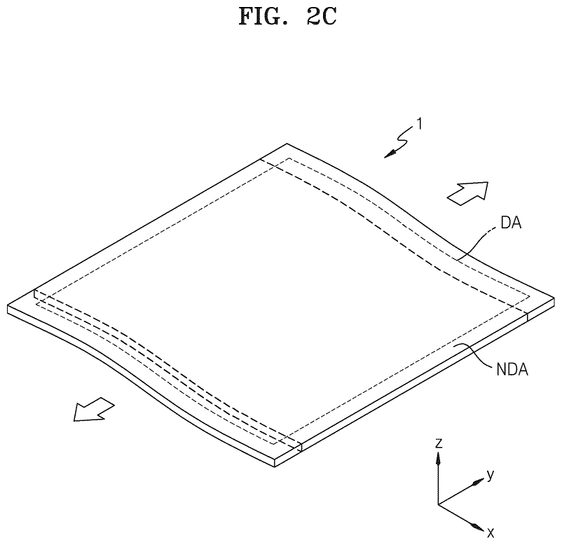

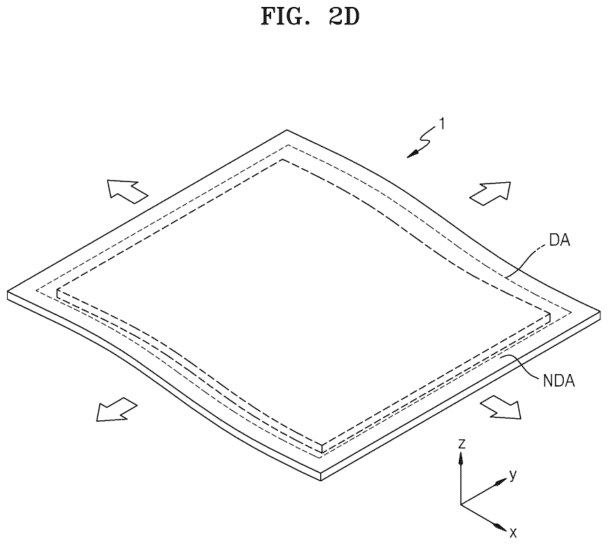

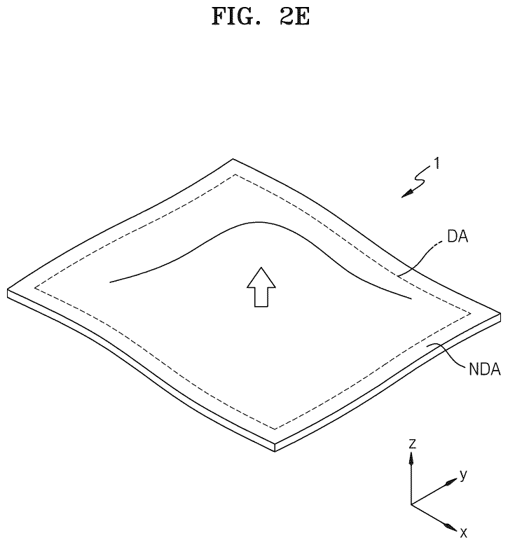

FIG. 1 is a schematic perspective view of a display device 1 according to one or more embodiments. FIGS. 2A and 2B are perspective views showing the display device 1 of FIG. 1 stretched in a first direction. FIG. 2C is a perspective view showing the display device 1 of FIG. 1 stretched in a second direction. FIG. 2D is a perspective view showing the display device 1 of FIG. 1 stretched in the first direction and the second direction. FIG. 2E is a perspective view showing the display device 1 of FIG. 1 stretched in a third direction.

Referring to FIG. 1, the display device 1 may include a display area DA and a non-display area NDA. The display area DA may include a plurality of pixels. The display device 1 may provide a corresponding image by using light emitted from the plurality of pixels. The non-display area NDA may be arranged outside the display area DA. The non-display area NDA is an area where pixels are not arranged, and may entirely surround the display area DA (e.g., in plan view).

The display device 1 may be freely deformable and/or stretchable. The display device 1 may stretch or shrink (e.g., “unstretch”) in various directions. The display device 1 may be stretched in a first direction (e.g., a direction x and/or a direction-x) by an external object or an external force applied by a user. In one or more embodiments, as shown in FIGS. 2A and 2B, the display area DA and/or the non- display area NDA of the display device 1 may be stretched in the first direction (e.g., the direction x and/or the direction −x). For example, the display area DA and/or the non-display area NDA of the display device 1 may be stretched in the direction x and the direction −x as shown in FIG. 2A, or may be stretched in the direction x with one side of the display device 1 fixed as shown in FIG. 2B.

The display device 1 may be stretched in a second direction (e.g., a direction y and/or a direction −y) by an external object or an external force applied by a user. In one or more embodiments, as shown in FIG. 2C, the display area DA and/or the non-display area NDA of the display device 1 may be stretched in the direction y and the direction −y. In one or more other embodiments, the display area DA and/or the non-display area NDA of the display device 1 may be stretched in the direction y or the direction −y with one side of the display device 1 fixed.

The display device 1 may be stretched in a plurality of directions, for

example, the first direction (e.g., the direction x and/or the direction −x) and the second direction (e.g., the direction y and/or the direction −y), by an external object or an external force applied by part of a human body. As shown in FIG. 2D, the display area 1 DA and/or the non-display area NDA of the display device 1 may be stretched in the direction ±x and the direction ±y.

The display device 1 may be stretched in a third direction (e.g., a direction z or a direction −z) by an external object or an external force applied by part of a human body. As one or more embodiments, FIG. 2E shows a portion of the display device 1, for example, a partial region of the display area DA, protruding in the direction z. In one or more other embodiments, a portion of the display device 1, for example, a partial region of the display area DA, may protrude in the direction −z (or be depressed in the direction z).

Although FIGS. 2A to 2E show the display device 1 stretched in the first direction, the second direction and/or the third direction, one or more embodiments are not limited thereto. In one or more other embodiments, the display device 1 may be deformed into various atypical shapes, such as being bent or twisted along two or more axes.

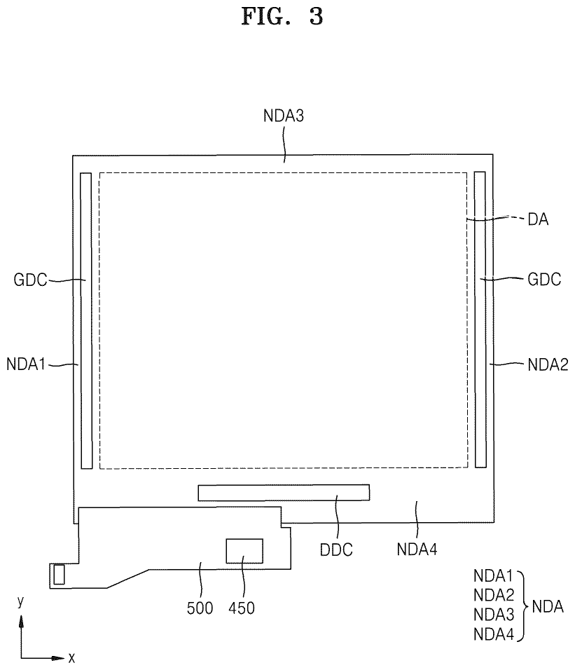

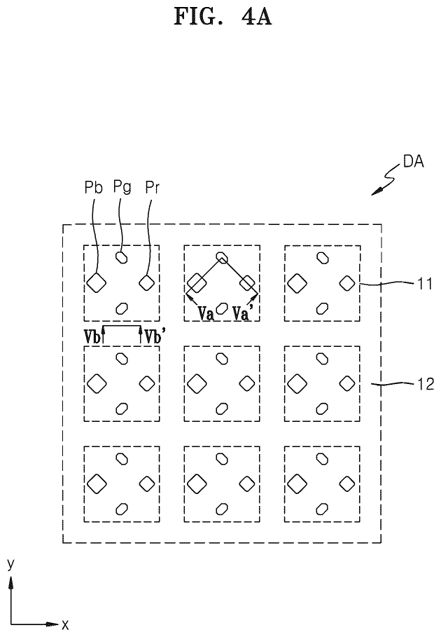

FIG. 3 is a schematic plan view of the display device 1 according to one or more embodiments.

A plurality of pixels may be arranged in the display area DA of the display device 1. Each pixel may include sub-pixels that emit light of different colors from one another. A light-emitting element corresponding to each sub-pixel may be arranged in the display area DA. A circuit for providing an electrical signal to light-emitting elements arranged in the display area DA and transistors electrically connected to the light-emitting elements may be in the non-display area NDA arranged around the display area DA. A gate-driving circuit GDC may be arranged in each of a first non- display area NDA1 and a second non-display area NDA2 arranged on respective sides of the display area DA. The gate-driving circuit GDC may include drivers for providing an electrical signal to a gate electrode of each of the transistors electrically connected to the light-emitting elements. Although FIG. 3 shows the gate-driving circuit GDC arranged in each of the first non-display area NDA1 and the second non-display area NDA2, one or more embodiments are not limited thereto. In one or more other embodiments, the gate-driving circuit GDC may be arranged in any one of the first non-display area NDA1 and the second non-display area NDA2.

A data-driving circuit DDC may be arranged in a third non-display area NDA3 and/or a fourth non-display area NDA4 connecting the first non-display area NDA1 and the second non-display area NDA2 to each other. As one or more embodiments, FIG. 3 shows the data-driving circuit DDC arranged in the fourth non-display area NDA4. In one or more other embodiments, the data-driving circuit DDC may be arranged in each of the third non-display area NDA3 and the fourth non-display area NDA4.

A circuit board 500 may be arranged at one end of the fourth non-display area NDA4. The circuit board 500 may overlap a pad portion arranged at one end of a substrate 100, for example, one end of the fourth non-display area NDA4, and may be electrically connected to the pad portion, or may be electrically connected to the pad portion via a flexible circuit film. The circuit board 500 may include a main processor required for the display device 1 to operate to display an image and a touch detector for sensing a touch input.

Although FIG. 3 shows the data-driving circuit DDC arranged in the fourth non-display area NDA4 of the display device 1, one or more embodiments are not limited thereto. In one or more other embodiments, the data-driving circuit DDC may be located on the circuit board 500.

In some embodiments, when the display device 1 is three-dimensionally deformed as shown in FIGS. 2A to 2E, an elongation rate of the non-display area NDA may be equal to or less than an elongation rate of the display area DA. In one or more embodiments, an elongation rate of the non-display area NDA may be different for each region. For example, the first non-display area NDA1, the second non-display area NDA2, and the third non-display area NDA3 may have substantially the same elongation rate, but an elongation rate of the fourth non-display area NDA4 may be less than the elongation rate of each of the first non-display area NDA1, the second non-display area NDA2, and the third non-display area NDA3. An elongation rate of the display area DA may also be different for each local region of the display area DA.

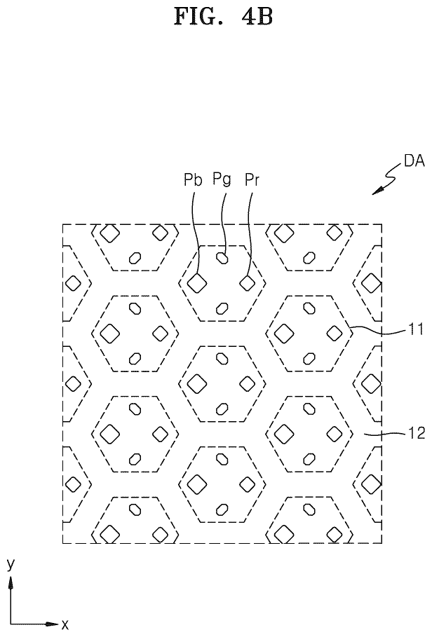

FIGS. 4A and 4B are plan views each showing an excerpt of a portion of the display area DA of a display device according to one or more embodiments.

Referring to FIGS. 4A and 4B, the display area DA may include first regions 11, and a second region 12 between the first regions 11. A first region 11 is a type of unit pixel, and may include pixels that emit light of different colors from one another.

In some embodiments, FIGS. 4A and 4B show pixels having a Diamond PenTile® arrangement in the display area DA (Diamond PenTile® and PENTILE™ being a registered trademark of Samsung Display Co., Ltd., Republic of Korea), and show unit pixels each including one blue pixel Pb, one red pixel Pr, and two green pixels Pg. The unit pixels may be minimum repeating units of pixels having a corresponding arrangement, and in some embodiments, the pixels may have various arrangements, such as a stripe arrangement, and each of the unit pixels may include one blue pixel Pb, one red pixel Pr, and one green pixel Pg.

The first region 11 may have a quadrangular shape as shown in FIG. 4A or may have a polygonal shape in plan view, such as a hexagonal shape as shown in FIG. 4B. The second region 12 is a region between the first regions 11, and may be a region that a signal line (e.g., a scan line, a data line, etc.) configured to provide a signal or a voltage line runs through.

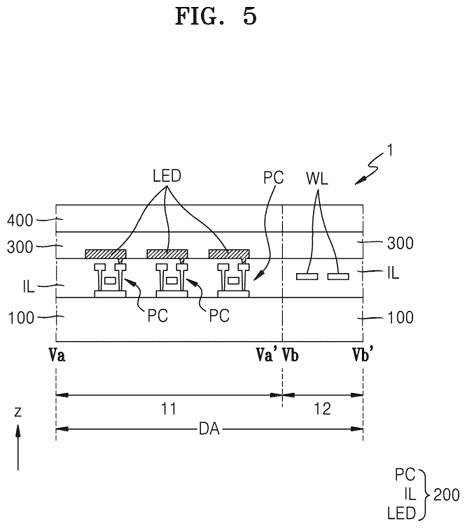

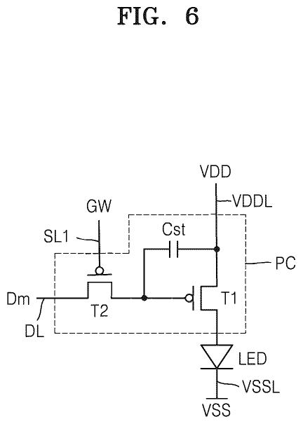

FIG. 5 is a cross-sectional view of a portion of the display area DA of the display device 1 according to one or more embodiments, taken along the line Va-Va′ and taken along the line Vb-Vb′ of FIG. 4A. FIG. 6 is a schematic equivalent circuit diagram of a pixel circuit PC and a light-emitting diode LED of FIG. 5.

Referring to FIG. 5, the display device 1 may include a display layer 200, a protection layer 300, and a touch layer 400 on the substrate 100. The substrate 100 may include a stretchable material, such as stretchable polymer resin. In some embodiments, the substrate 100 may include an elastomer. The elastomer may include an organic elastomer, an organic-inorganic elastomer, or a combination thereof. For example, the substrate 100 may include a silicone-based elastomer, such as polydimethylsiloxane, a styrene-based elastomer, an olefin-based elastomer, polyurethane, or a mixture thereof. The substrate 100 may have a single-layer or multi-layer structure.

The display layer 200 may include the pixel circuit PC positioned in the first region 11 and a light-emitting element, for example, the light-emitting diode LED, electrically connected to the pixel circuit PC. The pixel circuit PC may include a transistor. In one or more embodiments, as shown in FIG. 6, the pixel circuit PC may include a first transistor T1, a second transistor T2, and a storage capacitor Cst. The pixel circuit PC may be electrically connected to a signal line and a voltage line. The signal line may include a scan line SL1 and a data line DL, and the voltage line may include a first voltage line VDDL and a second voltage line VSSL.

The second transistor T2 may be electrically connected to the scan line SL1 and the data line DL. The scan line SL1 may be configured to provide a scan signal GW to a gate electrode of the second transistor T2. The second transistor T2 may be configured to transmit a data signal Dm input from the data line DL to the first transistor T1 according to the scan signal GW input from the scan line SL1.

The storage capacitor Cst may be electrically connected to the second transistor T2 and the first voltage line VDDL, and may store a voltage corresponding to a difference between a voltage received from the second transistor T2 and a first power voltage VDD supplied by the first voltage line VDDL.

The first transistor T1 is a driving transistor, and may be configured to control a driving current flowing through the light-emitting diode LED. The first transistor T1 may be connected to the first voltage line VDDL and the storage capacitor Cst. The first transistor T1 may be configured to control a driving current flowing from the first voltage line VDDL to the light-emitting diode LED in response to a voltage value stored in the storage capacitor Cst. The light-emitting diode LED may emit light having a corresponding luminance according to the driving current. A first electrode of the light-emitting diode LED may be electrically connected to the first transistor T1, and a second electrode of the light-emitting diode LED may be electrically connected to a second voltage line VSSL configured to supply a second power voltage VSS.

Referring to FIG. 5 again, the display layer 200 may include at least one insulating layer IL between elements (a semiconductor layer, an electrode, etc.) of the pixel circuit PC, and/or between the pixel circuit PC and the light-emitting diode LED.

The signal line (e.g., a scan line, a data line, etc.) and/or the voltage line (e.g., a first voltage line, a second voltage line, etc.) electrically connected to the transistor of the pixel circuit PC may be electrically connected to the pixel circuit PC positioned in another first region 11, and in this regard, FIG. 5 shows a conductive line WL positioned in the second region 12. The conductive line WL may correspond to the signal line (e.g., a scan line, a data line, etc.) and/or the voltage line (e.g., a first voltage line, a second voltage line, etc.).

The protection layer 300 may be located over the light-emitting diode LED, and may protect the light-emitting diode LED or planarize the top of the light-emitting diode LED. The protection layer 300 may include an inorganic protection layer and/or an organic protection layer. In some embodiments, the protection layer 300 may include a structure in which an inorganic protection layer including an inorganic insulating material, an organic protection layer including an organic insulating material, and an inorganic protection layer including an inorganic insulating material are stacked on one another.

In one or more other embodiments, the protection layer 300 may include an organic material, such as resin, and may be a single layer including the aforementioned organic material. In some embodiments, the protection layer 300 may include urethane epoxy acrylate. The protection layer 300 may include a photosensitive material, for example, photoresist.

The touch layer 400 may be located on the protection layer 300 (as used herein, “located on” may mean “above”). The touch layer 400 may include touch electrodes and touch-insulating layers respectively located under and above the touch electrodes.

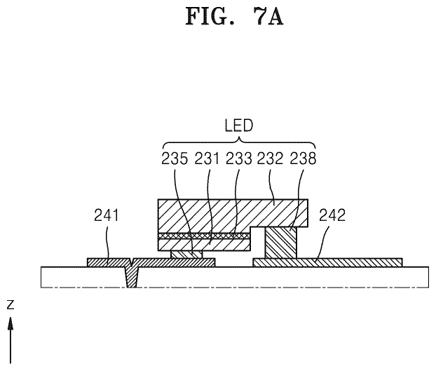

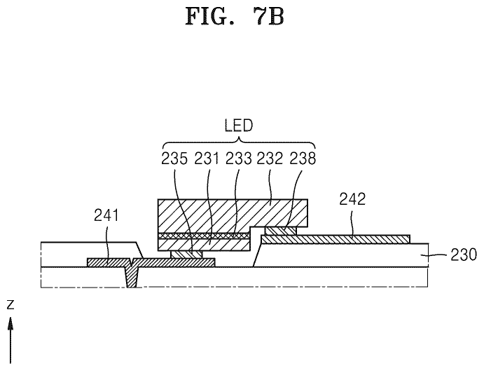

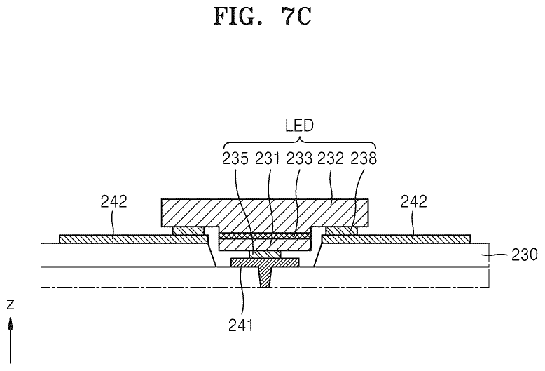

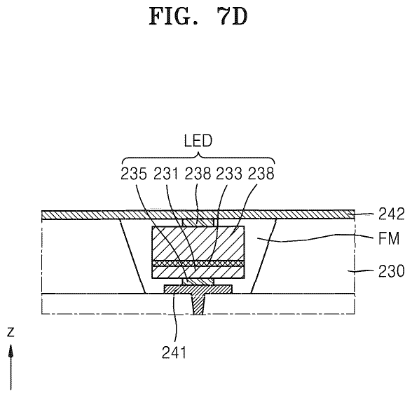

FIGS. 7A to 7D are schematic cross-sectional views of the light-emitting diode LED of a display device according to one or more embodiments.

Referring to FIG. 7A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242, respectively, which may be located at a same layer as each other. The second electrode pad 242 may be a portion of the second voltage line VSSL (of FIG. 6) described above with reference to FIG. 6 or may be a conductive layer electrically connected to the second voltage line VSSL (of FIG. 6).

In some embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, etc., and may be doped with a p-type dopant, such as Mg, Zn, Ca, Sr, Ba, etc.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, 0≤+y≤1), for example, GaN, AlN, AlGaN, InGaN, InN, InAlGaN, AlInN, etc., and may be doped with an n-type dopant, such as Si, Ge, Sn, etc.

The intermediate layer 233 is an area where electrons and holes recombine with each other, and transition to a lower energy level when the electrons and the holes recombine, and accordingly, light having a wavelength corresponding to the transitioned energy level is emitted. The intermediate layer 233 may include, for example, a semiconductor material having a composition formula of InₓAl_{y}Ga_{1-x-y}N (0≤x≤1, 0≤y≤1, 0≤x+y≤1), and may have a single quantum well structure or a multi-quantum well (MQW) structure. In addition, the intermediate layer 233 may include a quantum wire structure or a quantum dot structure.

Although FIG. 7A illustrates that the first semiconductor layer 231 includes a p-type semiconductor layer, and the second semiconductor layer 232 includes an n-type semiconductor layer, one or more embodiments are not limited thereto. In one or more other embodiments, the first semiconductor layer 231 may include an n-type semiconductor layer, and the second semiconductor layer 232 may include a p-type semiconductor layer.

Although FIG. 7A shows the first electrode pad 241 and the second electrode pad 242 located on the same layer, one or more embodiments are not limited thereto. Referring to FIG. 7B, the first electrode pad 241 and the second electrode pad 242 may be located on different layers from each other. For example, a bank layer 230 may include an opening overlapping at least a portion of the first electrode pad 241 above the first electrode pad 241, and the second electrode pad 242 may be located on an upper surface of the bank layer 230. A structure of the light-emitting diode LED shown in FIG. 7B is the same as described above with reference to FIG. 7A.

In one or more other embodiments, as shown in FIG. 7C, the second electrode pad 242 may be arranged at both sides of the first electrode pad 241 in the cross-sectional view. The bank layer 230 may include an opening overlapping at least a portion of the first electrode pad 241, and the second electrode pad 242 may be arranged around the opening of the bank layer 230. In some embodiments, in plan view, the second electrode pad 242 may have a closed loop shape entirely surrounding the opening of the bank layer 230 and/or the first electrode pad 241. A structure of the light-emitting diode LED shown in FIG. 7C is the same as described above with reference to FIG. 7A.

Although FIGS. 7A to 7C show that the first electrode 235 and the second electrode 238 of the light-emitting diode LED face the same direction (e.g., a downward direction, a direction −z), one or more embodiments are not limited thereto. As shown in FIG. 7D, the first electrode 235 and the second electrode 238 of the light-emitting diode LED may face directions that are opposite to each other.

The bank layer 230 may include an opening exposing at least a portion of the first electrode pad 241, and a thickness of the bank layer 230 may be substantially the same as a thickness of the light-emitting diode LED. The opening of the bank layer 230 may be filled with a filling material FM, and the second electrode pad 242 may be located on an upper surface of the bank layer 230 to be electrically connected to (e.g., in contact with) the second electrode 238 of the light-emitting diode LED. The filling material FM may be an organic material with insulating properties.

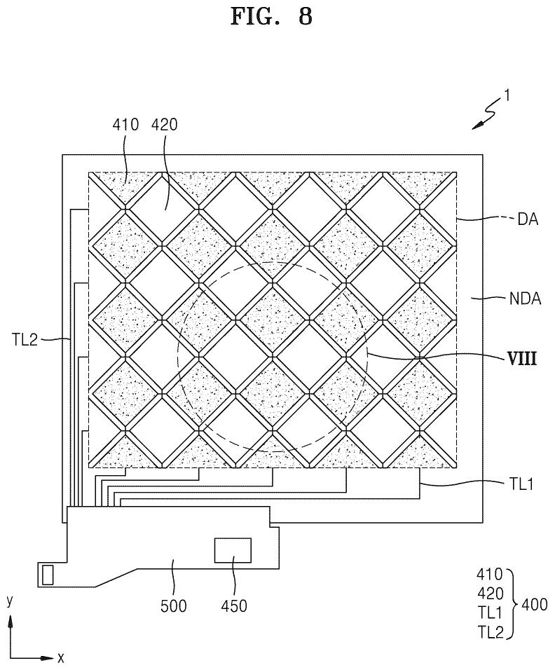

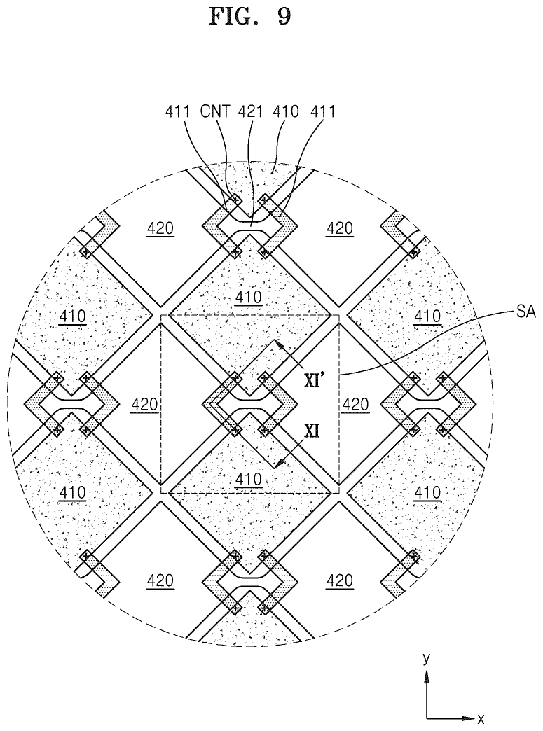

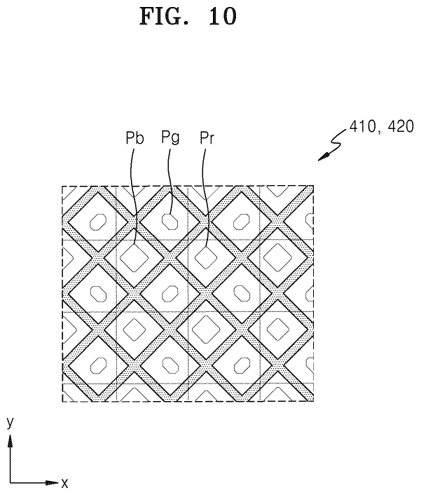

FIG. 8 is a schematic plan view of the touch layer 400 of the display device 1 according to one or more embodiments. FIG. 9 is an enlarged plan view of a region VIII of FIG. 8.

Referring to FIG. 8, the touch layer 400 of the display device 1 may include mutual capacitance type touch electrodes. The touch electrodes may include first touch electrodes 410 arranged in a direction y, and second touch electrodes 420 arranged in a direction x crossing the direction y. The first touch electrodes 410 may be arranged such that corners thereof are adjacent to each other in the direction y, and between the first touch electrodes 410, the second touch electrodes 420 may be arranged such that corners thereof are adjacent to each other in the direction x.

The first touch electrodes 410 arranged in the direction y in the display area DA are electrically connected to each other, and the second touch electrodes 420 arranged in the direction x in the display area DA are also electrically connected to each other. For example, as shown in FIG. 9, the first touch electrodes 410 may be electrically connected to each other through a first connection electrode 411, and the second touch electrodes 420 may be electrically connected to each other through a second connection electrode 421.

Referring to FIG. 9, the display area DA may include a plurality of sub-areas SA arranged in a matrix form in the direction x and the direction y, and each sub-area

SA may be an area corresponding to some portions of two adjacent first touch electrodes 410 and some portions of two adjacent second touch electrodes 420. An arrangement of the first touch electrodes 410 and the second touch electrodes 420 may be substantially the same as a repetitive arrangement of touch electrodes corresponding to the sub-area SA described above.

In some embodiments, the sub-area SA described above may be a virtual unit block with a corresponding area that overlaps some portions of two adjacent first touch electrodes 410 and some portions of two adjacent second touch electrodes 420, and may correspond to a minimum repeating unit of an arrangement pattern of the first and second touch electrodes 410 and 420.

Columns of first touch electrodes 410 extending in the direction y may be electrically connected to first trace lines TL1 arranged in the non-display area NDA. Rows of second touch electrodes 420 extending in the direction x may be electrically connected to second trace lines TL2 arranged in the non-display area NDA. The first and second trace lines TL1 and TL2 may electrically connect the first touch electrodes 410 and the second touch electrodes 420 to a touch detector (e.g., touch-detecting unit) 450. The touch detector 450 may be provided on the circuit board 500.

FIG. 10 is an enlarged plan view of part of a first touch electrode 410 and a second touch electrode 420 of a display device according to one or more embodiments.

Each of the first touch electrode 410 and the second touch electrode 420 according to one or more embodiments may include mesh-shaped conductive lines as shown in FIG. 10. The mesh-shaped conductive lines may at least partially (e.g., either entirely or partially) surround each pixel. As one or more embodiments, FIG. 10 shows a blue pixel Pb, a green pixel Pg, and a red pixel Pr each having a structure surrounded by the mesh-shaped conductive lines. The blue pixel Pb, the green pixel Pg, and the red pixel Pr may be positioned in openings of the mesh-shaped conductive lines in plan view.

In one or more other embodiments, two neighboring openings of the mesh-shaped conductive lines may be spatially connected to each other, and the blue pixel Pb, the green pixel Pg, and/or the red pixel Pr may be partially surrounded by the mesh-shaped conductive lines.

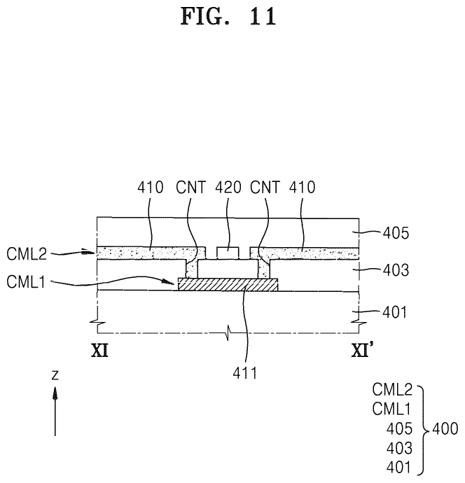

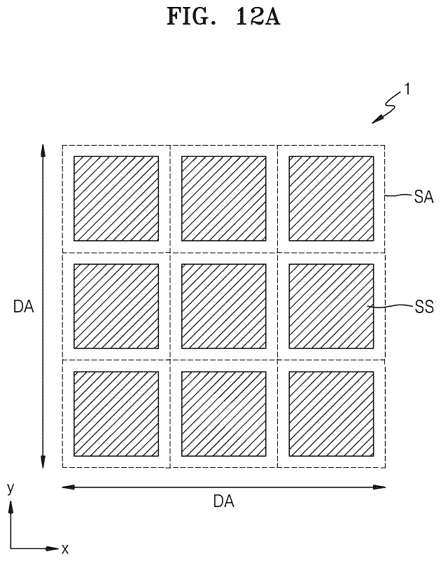

FIG. 11 is a cross-sectional view of a touch layer, taken along the line XI-XI′ of FIG. 9.

Referring to FIG. 11, the touch layer 400 may include a first conductive pattern layer CML1 and a second conductive pattern layer CML2 located over the protection layer 300. A first touch-insulating layer 401 may be located between the protection layer 300 and the first conductive pattern layer CML1, a second touch-insulating layer 403 may be located between the first conductive pattern layer CML1 and the second conductive pattern layer CML2, and a third touch-insulating layer 405 may be on the second conductive pattern layer CML2.

The first conductive pattern layer CML1 and the second conductive pattern layer CML2 may include a conductive material. For example, the first conductive pattern layer CML1 and the second conductive pattern layer CML2 may each include a metallic conductive material, such as at least one selected from molybdenum (Mo), silver (Ag), titanium (Ti), copper (Cu), and aluminum (Al). In some embodiments, the first conductive pattern layer CML1 and the second conductive pattern layer CML2 may each include a conductive composite in which metal nanostructures, etc., are dispersed in a polymer resin. The conductive composite may include an elastomer and may further include additives, such as carbon nanotubes, carbon fiber, graphene, and graphene oxide, to have improved conductivity. In one or more other embodiments, the first conductive pattern layer CML1 and the second conductive pattern layer CML2 may each include a liquid metal material, such as eutectic gallium-indium alloy. The first conductive pattern layer CML1 and the second conductive pattern layer CML2 may each have a single-layer or multi-layer structure including the above-described conductive material.

The first touch-insulating layer 401, the second touch-insulating layer 403, and the third touch-insulating layer 405 may each include an inorganic insulating material, such as silicon oxide, silicon nitride and/or silicon oxynitride, or an organic insulating material.

Some of the first touch electrodes 410, the second touch electrodes 420, first connection electrodes 411, and second connection electrodes 421 may be positioned in the first conductive pattern layer CML1, and others may be positioned in the second conductive pattern layer CML2. For example, the first conductive pattern layer CML1 may include the first connection electrodes 411, and the second conductive pattern layer CML2 may include the first touch electrodes 410, the second touch electrodes 420, and the second connection electrodes 421.

Referring to FIGS. 9 and 11, adjacent second touch electrodes 420 are electrically connected to each other through a second connection electrode 421 positioned on the same layer. Adjacent first touch electrodes 410 are electrically connected to each other through a first connection electrode 411, and may be connected to the first connection electrode 411 through a contact hole CNT penetrating the second touch-insulating layer 403.

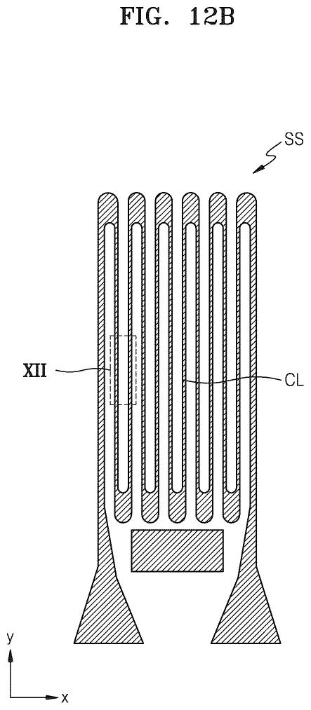

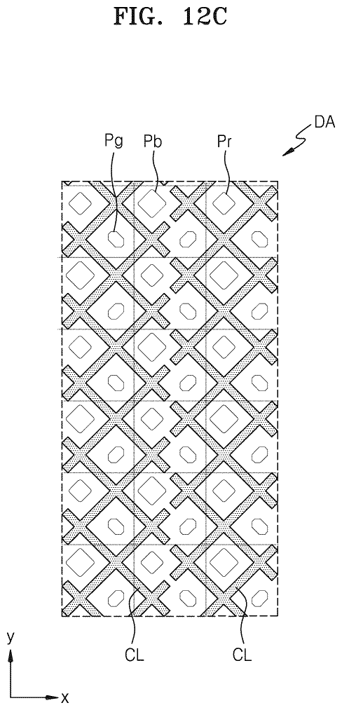

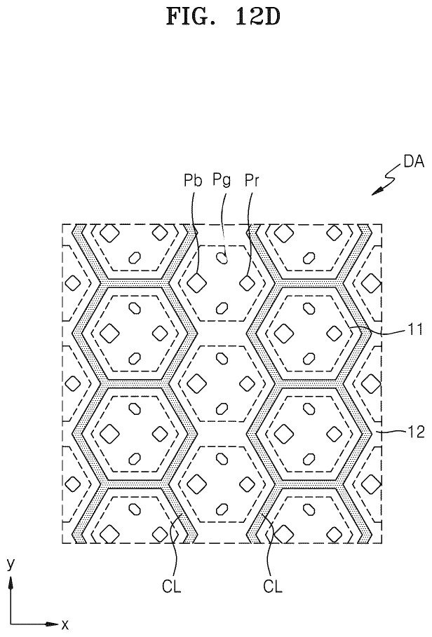

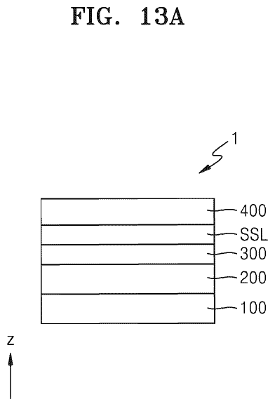

FIG. 12A is a schematic plan view of an arrangement of strain sensors SS included in the display device 1 according to one or more embodiments. FIG. 12B is a plan view of a portion of any one strain sensor SS of FIG. 12A. FIGS. 12C and 12D are enlarged plan views each showing a region XII of FIG. 12B.

Referring to FIG. 12A, the display device 1 may include a plurality of sub- areas SA arranged in the display area DA, and the strain sensor SS may be arranged in each sub-area SA.

As shown in FIG. 12B, the strain sensor SS may include a conductive line CL having a serpentine shape. The conductive line CL may include a conductive material, for example, a metallic material, a conductive composite in which metal nanostructures, etc., are dispersed in a polymer resin, or a liquid metal material. The conductive composite may include an elastomer, and may further include additives, such as carbon nanotubes, carbon fiber, graphene, and graphene oxide, to have improved conductivity. The liquid metal material may include a material, such as eutectic gallium-indium alloy.

The conductive line CL may be arranged in the display area DA as shown in FIGS. 12C and 12D, and may have a mesh shape. The conductive line CL may have a mesh shape entirely or partially surrounding at least one pixel (e.g., the blue pixel Pb, the green pixel Pg, and/or the red pixel Pr) in plan view. In one or more embodiments, the conductive line CL may have a mesh shape entirely or partially surrounding each pixel (e.g., the blue pixel Pb, the green pixel Pg, or the red pixel Pr) as shown in FIG. 12C, or may have a mesh shape entirely or partially surrounding the first region 11 corresponding to a unit pixel as shown in FIG. 12D. When the conductive line CL is referred to as entirely or partially surrounding the first region 11 corresponding to a unit pixel, the conductive line CL may entirely or partially surround a plurality of pixels (e.g., the blue pixel Pb, the green pixel Pg, and the red pixel Pr).

The strain sensors SS may sense an elongation rate of each sub-area SA when the display device is deformed, for example, when the display area DA is stretched. In some embodiments, the strain sensor SS may have resistance of the strain sensor SS itself changed when each sub-area SA is stretched, and the display device 1 may obtain information regarding an elongation rate of each sub-area SA by using a change in resistance of the strain sensor SS.

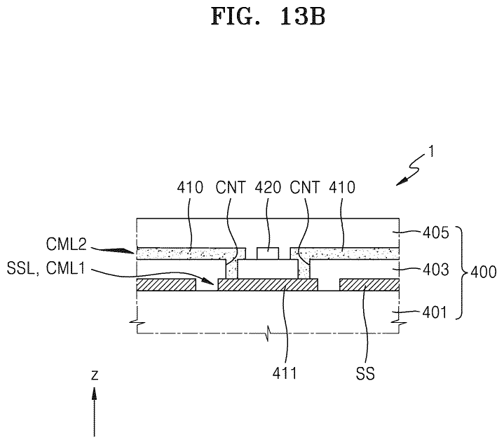

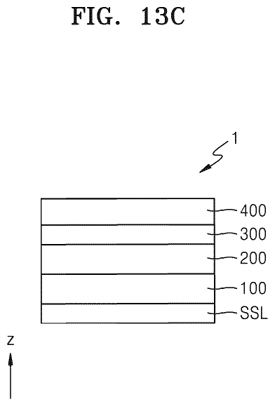

FIGS. 13A to 13C are schematic cross-sectional views each showing a portion of the display device 1 including a strain sensor.

The strain sensors SS shown in FIGS. 12A and 12B may be located on the same layer. A layer on which the strain sensors SS are located (hereinafter referred to as a sensor layer SSL) may be located between the protection layer 300 and the touch layer 400 as shown in FIG. 13A. In one or more other embodiments, the strain sensor SS may be located on a layer on which the first conductive pattern layer CML1 and the first connection electrode 411 are located as shown in FIG. 13B. In other words, the first conductive pattern layer CML1 may be the sensor layer SSL. In one or more other embodiments, as shown in FIG. 13C, the sensor layer SSL may be located on (e.g., below) the substrate 100, for example, on a bottom surface of the substrate 100.

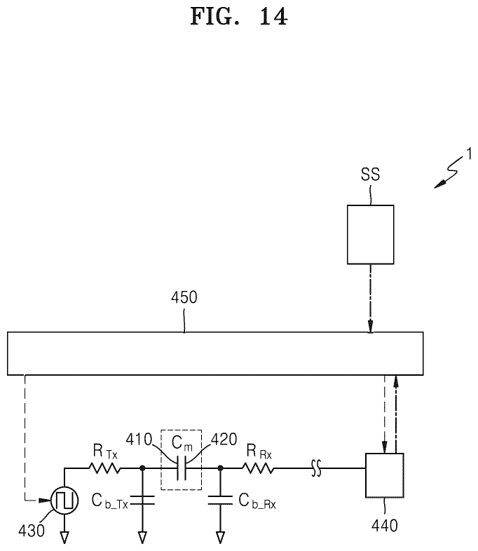

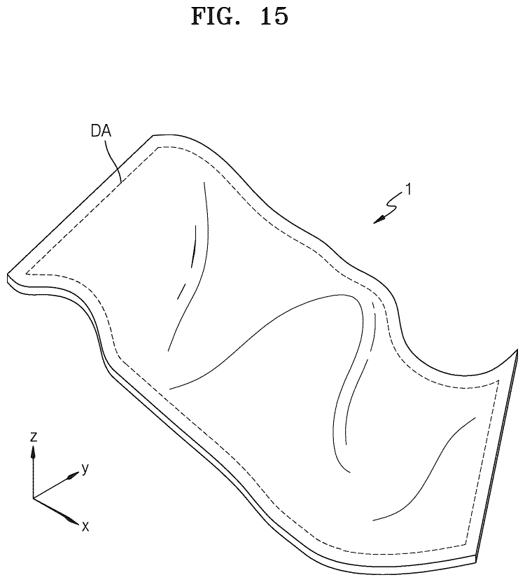

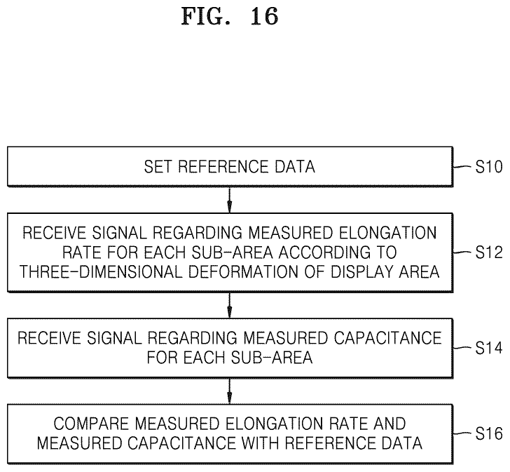

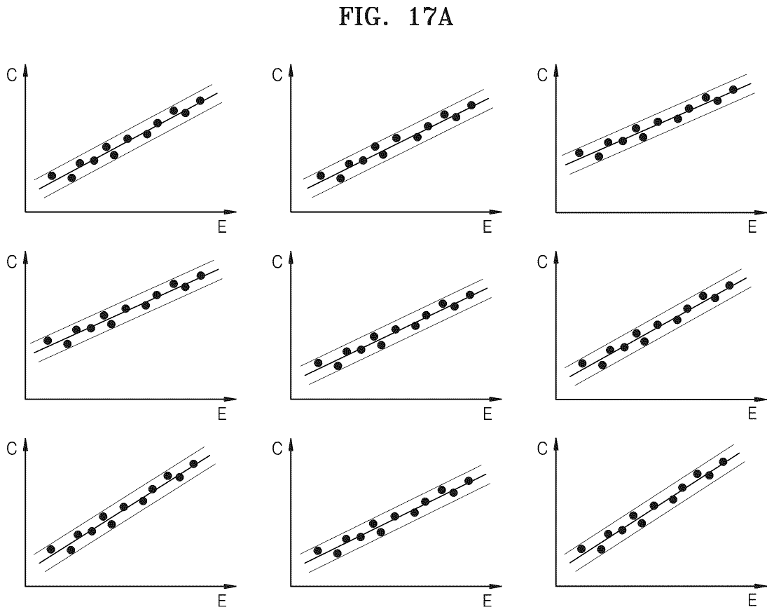

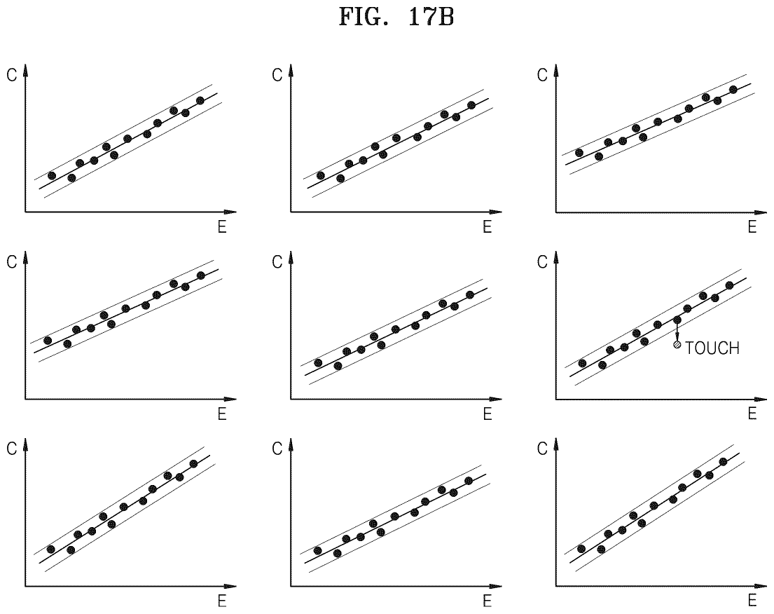

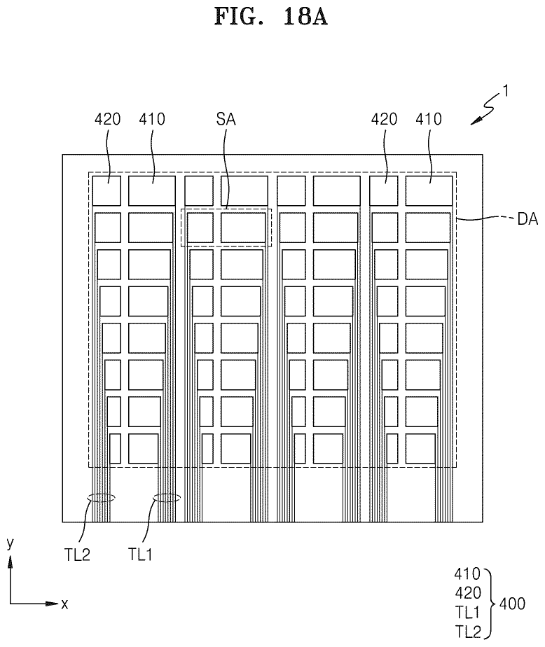

FIG. 14 is a diagram of the display device 1 according to one or more embodiments, mainly showing a touch electrode. FIG. 15 is a perspective view showing a three-dimensional deformation state of the display device 1 according to one or more embodiments. FIG. 16 is a flowchart showing operations of a touch detector according to one or more embodiments. FIG. 17A is a graph for visually explaining reference data for each sub-area. FIG. 17B is a graph for visually explaining how a touch detector senses a touch input.

Referring to FIG. 14, a signal supplier (e.g., signal supply unit) 430 of the display device 1 may output a touch-driving signal to a touch electrode (e.g., the first touch electrode 410) through a first trace line TL1 shown in FIG. 8. The touch-driving signal may include a plurality of pulses.

A signal receiver (e.g., signal-receiving unit) 440 may sense a voltage charged in a mutual capacitance Cm through a second trace line TL2 electrically connected to the second touch electrodes 420. The mutual capacitance that is formed between the first touch electrode 410 and the second touch electrode 420 before a touch input may be denoted as “Cm,” and a first parasitic capacitance C_{b_Tx} may be formed between the first touch electrode 410 and a lower conductive layer with a corresponding voltage under the first touch electrode 410, and a second parasitic capacitance C_{b_Rx} may be formed between the second touch electrode 420 and a lower conductive layer with a corresponding voltage under the second touch electrode 420. In one or more embodiments, the lower conductive layer described above may be the second electrode pad 242 described above with reference to FIGS. 7A to 7D, and the second electrode pad 242 may have a voltage level of the second power voltage VSS as referred to above in FIG. 6. In one or more other embodiments, the lower conductive layer described above may be the strain sensor SS described with reference to FIGS. 12A to 12D and FIGS. 13A and 13B. In FIG. 14, R_{Tx} denotes resistance of the first touch electrode 410, and R_{Rx} denotes resistance of the second touch electrode 420.

When a touch input from a body part, such as a finger is applied to the display device 1, capacitance may be formed between the body part and the first touch electrode 410 and/or between the body part and the second touch electrode 420 in addition to the mutual capacitance Cm between the first touch electrode 410 and the second touch electrode 420. When there is a touch input, the mutual capacitance that is formed between the first touch electrode 410 and the second touch electrode 420 may be reduced to “Cm−ΔCm” compared to a case where there is no touch input.

The touch detector 450 may control an operation of the signal supplier 430, may receive a signal regarding mutual capacitance from the signal receiver 440, and may receive a signal regarding a tensile modulus of each sub-area measured by the strain sensor SS.

In some embodiments, the display device 1 may be freely deformed three-dimensionally as shown in FIGS. 2A to 2D and FIG. 15, and may provide a three-dimensional image plane through the display area DA. In one or more embodiments, the description “freely deformable three-dimensionally” is distinct from operations of a rollable display device, such as a case where only part of a display area of a rolled-up display device is visible to a user, and then the other part of the rolled-up display device unfolds, and the entire display area is visible to the user (or a case where the entire display area is visible to a user through an unfolded display device and then the display device is rolled up and only part of the display area is visible to the user), and may refer to deformation, such as the area of the entire display area DA increasing or again decreasing as the display device 1 is deformed in a direction x, a direction y and/or direction z.

As a comparative example, in a display device that provides a flat image plane, when there is a touch input to the display device, the touch input may be sensed through a change in mutual capacitance between first and second touch electrodes, whereas, in the display device 1 according to one or more embodiments of the present application, which is capable of providing a three-dimensional image plane as shown in FIG. 15, the touch detector 450 may sense a touch input by receiving signals from the signal receiver 440 and the strain sensor SS described above with reference to FIG. 14, respectively.

Referring to FIG. 16, the touch detector 450 (of FIG. 14) sets reference data (in step S10). In one or more embodiments, the touch detector 450 may set reference data based on a data setting command. The touch detector 450 may set reference data by receiving an elongation rate in each sub-area SA according to three-dimensional deformation of the display device 1 and capacitance of touch electrodes corresponding to each sub-area SA. When the display device 1 is three-dimensionally deformed, the touch detector 450 may collect an elongation rate and capacitance of touch electrodes for each sub-area SA. The touch detector 450 may receive signals regarding an elongation rate and capacitance of each sub-area SA several to dozens of times, and may set reference data based on the received signals.

In some embodiments, as shown in FIG. 17A, the touch detector 450 may set the relationship between an elongation rate E corresponding to each sub-area SA and a capacitance C of touch electrodes as reference data. A reference range may be set as shown in FIG. 17A by receiving signals regarding an elongation rate and capacitance of each sub-area SA according to three-dimensional deformation of the display device 1 occurring during a corresponding period (e.g., a reference data setting period) several to dozens of times. Each graph shown in FIG. 17A may show reference data for each sub-area SA.

Referring to FIG. 16 again, after the reference data setting period, the user may use the display device 1 while three-dimensionally transforming the display device 1 as shown in FIG. 15, and may also perform a touch input using his or her body part, such as a finger. The display device 1 may receive a signal regarding each of an elongation rate (hereinafter referred to as a measured elongation rate) for each sub-area SA according to three-dimensional deformation of the display device 1, that is, three-dimensional deformation of the display area DA (in step S12). The display device 1 may also receive a signal regarding each of capacitance (hereinafter referred to as measured capacitance) of touch electrodes for each sub-area SA according to three-dimensional deformation of the display device 1, that is, three-dimensional deformation of the display area DA (in step S14).

The touch detector 450 may sense a touch input by comparing the measured elongation rate and the measured capacitance with the reference data (in step S16). For example, as shown in FIG. 17B, when the measured elongation rate and the measured capacitance of any one sub-area SA among the sub-areas SA deviate from the reference data (e.g., a reference range on the graph), the touch detector 450 may sense that a touch input has occurred at a position corresponding to the corresponding sub-area SA.

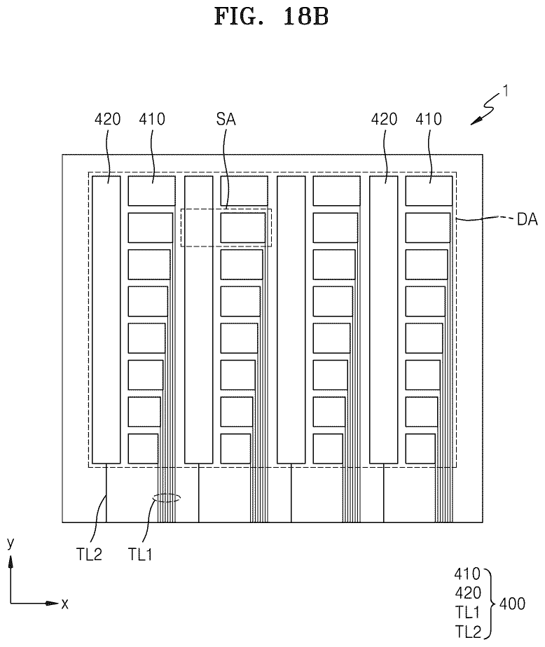

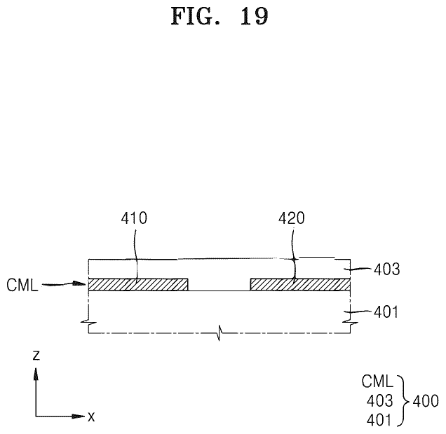

According to the previous embodiments described with reference to FIGS. 8 to 11, touch electrodes of the touch layer 400 are shown as including the first touch electrodes 410 arranged in the direction y, and electrically connected to each other and the second touch electrodes 420 arranged in the direction x and electrically connected to each other, and the touch layer 400 is shown as including the first conductive pattern layer CML1 and the second conductive layer CL2. However, one or more embodiments are not limited thereto, and the touch electrodes may include various structures as shown in FIGS. 18A, 18B, and 19 described below.

FIGS. 18A and 18B are schematic plan views each showing the touch layer 400 of the display device 1 according to one or more embodiments. FIG. 19 is a cross-sectional view of a portion of the touch layer 400 shown in FIGS. 18A and 18B.

Referring to FIG. 18A, touch electrodes may include a column of first touch electrodes 410 and a column of second touch electrodes 420 arranged in the display area DA. In one or more embodiments, a column of first touch electrodes 410 arranged in a direction y and a column of second touch electrodes 420 arranged in the direction y may alternate with each other in a direction x. The first touch electrodes 410 arranged in the direction y may be electrically insulated from each other, and the second touch electrodes 420 arranged in the direction y may be electrically insulated from each other. Each of the first touch electrodes 410 may be electrically connected to the first trace line TL1, and each of the second touch electrodes 420 may be electrically connected to the second trace line TL2. The first trace line TL1 and the second trace line TL2 may pass through the display area DA.

The first touch electrodes 410, the first trace lines TL1, the second touch electrodes 420, and the second trace lines TL2 may be formed on the same layer. For example, as shown in FIG. 19, the touch layer 400 may include a conductive pattern layer CML located between the first touch-insulating layer 401 and the second touch- insulating layer 403, and the conductive pattern layer CML may include the first touch electrodes 410, the second touch electrodes 420, the first trace line TL1, and the second trace line TL2.

The first touch electrodes 410, the first trace lines TL1, the second touch electrodes 420, and the second trace lines TL2 may each include mesh-shaped conductive lines, as previously shown in FIG. 10. The mesh-shaped conductive lines may at least partially surround each pixel, and may include a conductive material (e.g., a metallic material), a conductive composite in which metal nanostructures, etc., are dispersed in a polymer resin, or a liquid metal material). The conductive composite may include an elastomer, and may further include additives, such as carbon nanotubes, carbon fiber, graphene, and graphene oxide, to have improved conductivity. The liquid metal material may include a material, such as eutectic gallium-indium alloy.

Although FIG. 18A shows a 1:1 correspondence between the first touch electrodes 410 and the second touch electrodes 420, one or more embodiments are not limited thereto. In one or more other embodiments, as shown in FIG. 18B, one second touch electrode 420 may be arranged in correspondence with a plurality of first touch electrodes 410. For example, one second touch electrode 420 may extend in the direction y to correspond to a column of first touch electrodes 410 arranged in the direction y.

When the display device 1 has an arrangement of touch electrodes shown in FIG. 18A, in one or more embodiments, the sub-area SA may correspond to an area including one first touch electrode 410 and one second touch electrode 420 that are adjacent to each other. When the display device 1 has an arrangement of touch electrodes shown in FIG. 18B, in one or more embodiments, the sub-area SA may correspond to an area including one first touch electrode 410 and a portion of the second touch electrode 420 that are adjacent to each other.

The strain sensor SS may be arranged as described above with reference to FIGS. 12A to 12D in the area corresponding to each sub-area SA shown in FIGS. 18A and 18B, and the touch detector 450 (of FIG. 14) may sense a touch input through the steps described with reference to FIGS. 14 and 16 to 17B.

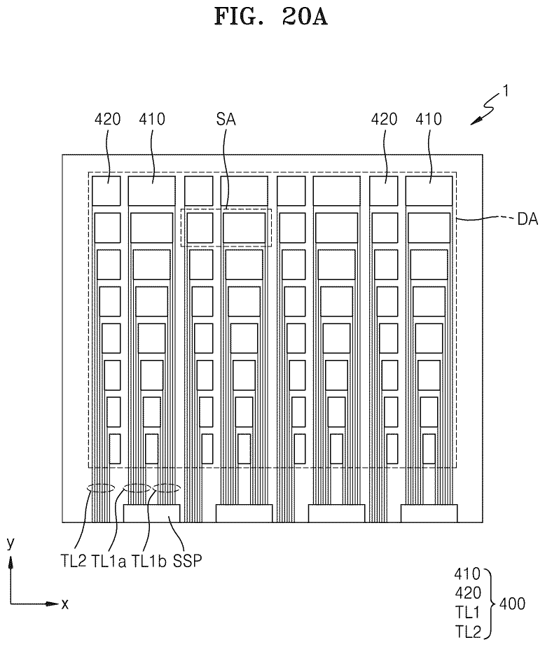

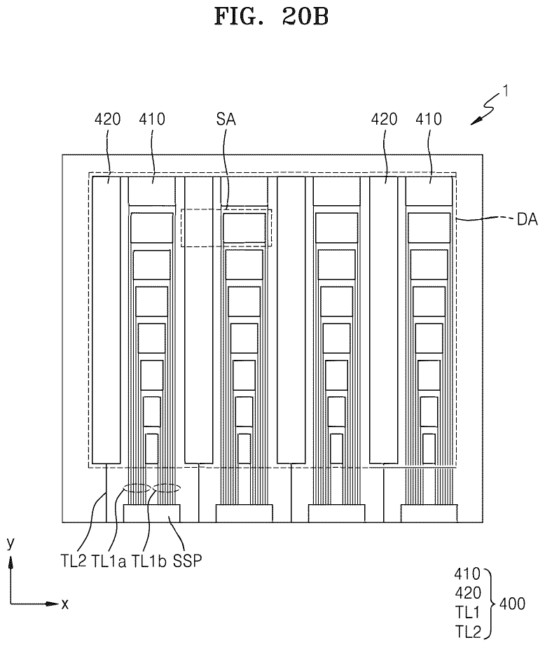

The strain sensor SS may be arranged in the display area DA (of FIG. 12A-12D) as shown in FIG. 12A-12D, but may also be arranged in the non-display area NDA of a display device as in FIGS. 20A and 20B described below.

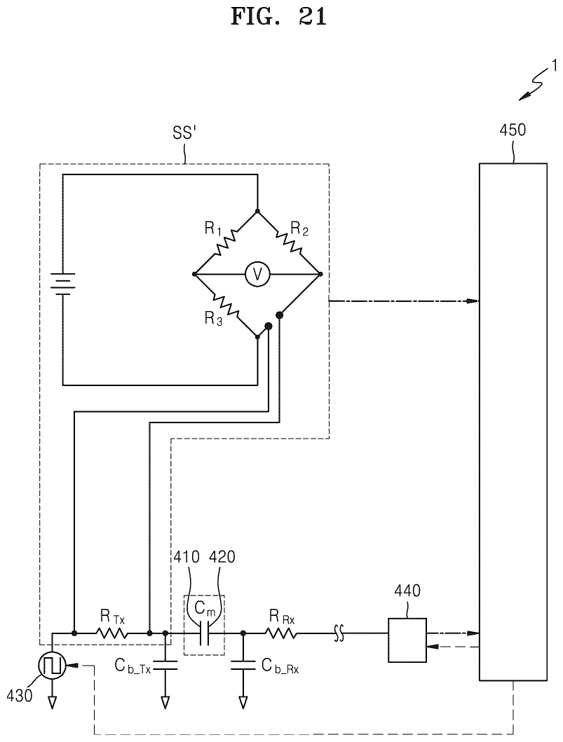

FIGS. 20A and 20B are schematic plan views each showing touch electrodes and a sensor portion SSP of the display device 1 according to one or more embodiments. FIG. 21 is a diagram of the display device 1 according to one or more embodiments, mainly showing a touch electrode and a strain sensor.

Referring to FIG. 20A, the display device 1 may include a column of first touch electrodes 410 and a column of second touch electrodes 420 alternating with each other in the display area DA. The first touch electrodes 410 may be electrically insulated from each other, and the second touch electrodes 420 may also be electrically insulated from each other.

Each of the first touch electrodes 410 may be electrically connected to a 1st-1 trace line TL1a and a 1st-2 trace line TL1b, and each of the second touch electrodes 420 may be electrically connected to the second trace line TL2. The 1st-1 trace line TL1a, the 1st-2 trace line TL1b, and the second trace line TL2 may pass through the display area DA.

The first touch electrodes 410, 1st-1 trace lines TL1a, 1st-2 trace lines TL1b, the second touch electrodes 420, and the second trace lines TL2 may be formed on the same layer. For example, as described with reference to FIG. 19, the touch layer 400 may include the conductive pattern layer CML located between the first touch-insulating layer 401 and the second touch-insulating layer 403, and the conductive pattern layer CML may include the first touch electrodes 410, the 1st-1 trace lines TL1a, the 1st-2 trace lines TL1b, the second touch electrodes 420, and the second trace lines TL2.

The first touch electrodes 410, the 1st-1 trace lines TL1a, the 1st-2 trace lines TL1b, the second touch electrodes 420, and the second trace lines TL2 may include mesh-shaped conductive lines as described above with reference to FIG. 10.

The mesh-shaped conductive lines may at least partially surround each pixel and may include a conductive material (e.g., a metallic material, a conductive composite in which metal nanostructures, etc., are dispersed in a polymer resin, or a liquid metal material). The conductive composite may include an elastomer, and may further include additives, such as carbon nanotubes, carbon fiber, graphene, and graphene oxide, to have improved conductivity. The liquid metal material may include a material, such as eutectic gallium-indium alloy.

Although FIG. 20A shows a 1:1 correspondence between the first touch electrodes 410 and the second touch electrodes 420, one or more embodiments are not limited thereto. In one or more other embodiments, as shown in FIG. 20B, one second touch electrode 420 may be arranged in correspondence with a plurality of first touch electrodes 410. For example, one second touch electrode 420 may extend in a direction y to correspond to a column of first touch electrodes 410 arranged in the direction y.

Referring to FIGS. 20A and 20B, the first touch electrodes 410 may be electrically connected to the sensor portion SSP arranged in the non-display area NDA. The sensor portion SSP may include strain sensors SS′ (of FIG. 21), and each strain sensor SS′ may include a Wheatstone bridge as shown in FIG. 21, and the Wheatstone bridge may include the first touch electrode 410. In FIG. 21, R_{Tx} denotes resistance of the first touch electrode 410.

Referring to FIGS. 20A to 21, the strain sensor SS′ may measure an elongation rate in the sub-area SA corresponding to the corresponding first touch electrode 410 through a structure of the Wheatstone bridge including the first touch electrode 410.

Each of resistances R1, R2, and R3 of a Wheatstone bridge electrically connected to the first touch electrode 410 relatively adjacent to the sensor portion SSP (among the first touch electrodes 410 arranged in one direction (e.g., the direction y)) may have a resistance value that is less than that of each of resistances R1, R2, and R3 of a Wheatstone bridge electrically connected to the first touch electrode 410 relatively far from the sensor portion SSP.

The signal supplier 430 (of FIG. 21) of the display device 1 may output a touch-driving signal to the first touch electrodes 410 through the 1st-1 trace line TL1a and/or the 1st-2 trace line TL1b. The touch-driving signal may include a plurality of pulses.

The signal receiver 440 may sense a voltage charged in the mutual capacitance Cm through the second touch electrodes 420, or through the second trace line TL2 electrically connected to the second touch electrode 420. The mutual capacitance that is formed between the first touch electrode 410 and the second touch electrode 420 before a touch input may be denoted as “Cm,” and the first parasitic capacitance C_{b_Tx} may be formed between the first touch electrode 410 and a lower conductive layer with a corresponding voltage under the first touch electrode 410, and the second parasitic capacitance C_{b_Rx} may be formed between the second touch electrode 420 and a lower conductive layer with a corresponding voltage under the second touch electrode 420. In one or more embodiments, the lower conductive layer described above may be the second electrode pad 242 described above with reference to FIGS. 7A to 7D, and the second electrode pad 242 may have a voltage level of the second power voltage VSS (of FIG. 6). In FIG. 21, R_{Tx} denotes resistance of the first touch electrode 410, and R_{Rx} denotes resistance of the second touch electrode 420.

When a touch input from a body part, such as a finger is applied to the display device 1, capacitance may be formed between the body part and the first touch electrode 410 and/or between the body part and the second touch electrode 420 in addition to the mutual capacitance Cm between the first touch electrode 410 and the second touch electrode 420. When there is a touch input, the mutual capacitance that is formed between the first touch electrode 410 and the second touch electrode 420 may be reduced to “Cm−ΔCm” compared to a case where there is no touch input.

The touch detector 450 may control an operation of the signal supplier 430, and may receive a signal regarding mutual capacitance from the signal receiver 440, and may receive a signal regarding a tensile modulus of each sub-area measured by the strain sensor SS′. Touch input sensing by the touch detector 450 is the same as described above with reference to FIGS. 16 to 17B.

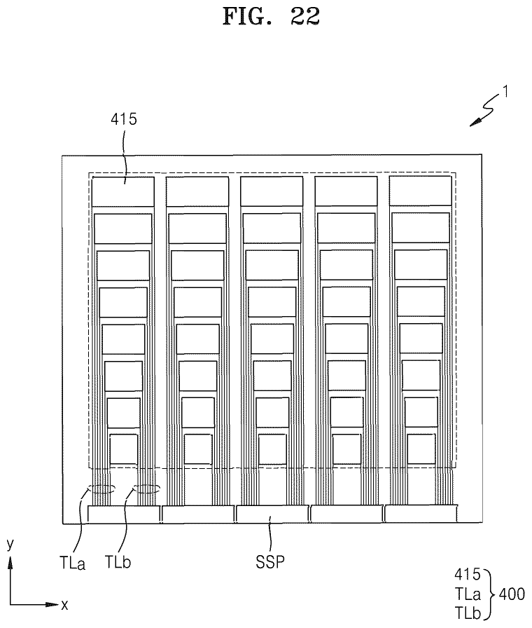

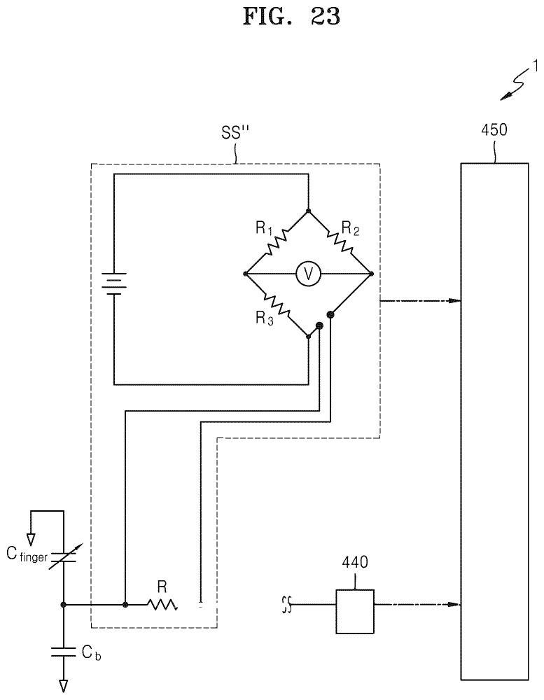

FIG. 22 is a schematic plan view of touch electrodes 415 and the sensor portion SSP of the display device 1 according to one or more embodiments. FIG. 23 is a diagram of the display device 1 according to one or more embodiments, mainly showing a touch electrode and a strain sensor.

Referring to FIG. 22, the display device 1 may include the touch electrodes 415 two-dimensionally arranged in the display area DA in rows and columns. Each of the touch electrodes 415 may be electrically connected to two trace lines, for example, first and second trace lines TLa and TLb. The first and second trace lines TLa and TLb may pass through the display area DA.

The touch electrodes 415, first trace lines TLa, and second trace lines TLb may be formed on the same layer. For example, as described with reference to FIG. 19, the touch layer 400 may include the conductive pattern layer CML located between the first touch-insulating layer 401 and the second touch-insulating layer 403, and the conductive pattern layer CML may include the touch electrodes 415, the first trace lines TLa, and the second trace lines TLb.

The touch electrodes 415, the first trace lines TLa, and the second trace lines TLb may include mesh-shaped conductive lines as described above with reference to FIG. 10. The mesh-shaped conductive lines may at least partially surround each pixel, and may include a conductive material (e.g., a metallic material, a conductive composite in which metal nanostructures, etc., are dispersed in a polymer resin, or a liquid metal material). The conductive composite may include an elastomer, and may further include additives, such as carbon nanotubes, carbon fiber, graphene, and graphene oxide, to have improved conductivity. The liquid metal material may include a material, such as eutectic gallium-indium alloy.

Referring to FIG. 22, the touch electrodes 415 may be electrically connected to the sensor portion SSP arranged in the non-display area NDA. The sensor portion SSP may include strain sensors SS″ (of FIG. 23), and each strain sensor SS″ may include a Wheatstone bridge as shown in FIG. 23 and the Wheatstone bridge may include a touch electrode 415.

Referring to FIGS. 22 and 23, through a structure of the Wheatstone bridge of which the touch electrode 415 is a part, the strain sensor SS″ may measure an elongation rate in the sub-area SA where the corresponding touch electrode 415 is positioned.

Each of resistances R1, R2, and R3 of a Wheatstone bridge electrically connected to the touch electrode 415 relatively adjacent to the sensor portion SSP (among the touch electrodes 415 arranged in one direction (e.g., the direction y)) may have a resistance value that is less than that of each of resistances R1, R2, and R3 of a Wheatstone bridge electrically connected to the touch electrode 415 relatively far from the sensor portion SSP.

The display device 1 shown in FIG. 22 may use a self-capacitance type touch-sensing method.

Before a touch input, a capacitance C_{b} may be formed between the touch electrode 415 and a lower conductive layer under the touch electrode 415. When a touch input from a body part, such as a finger is applied to the display device 1, a capacitance C_{finger} may be formed between the body part and the touch electrode 415 in addition to the capacitance C_{b} between the touch electrode 415 and the lower conductive layer. When there is a touch input, capacitance may be increased compared to a case where there is no touch input. The signal receiver 440 may convert a signal correspond to “C_{b}+C_{finger}” into a digital signal, and may provide the digital signal to the touch detector 450.

The touch detector 450 may receive a signal regarding capacitance from the signal receiver 440 and a signal regarding a tensile modulus of each sub-area measured by the strain sensor SS″. Touch input sensing by the touch detector 450 is the same as described above with reference to FIGS. 16 to 17B.

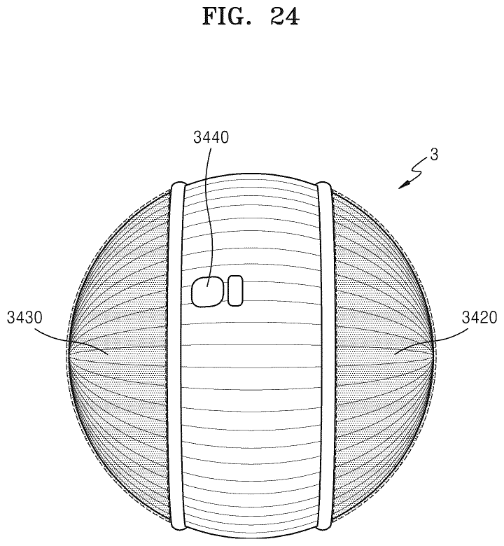

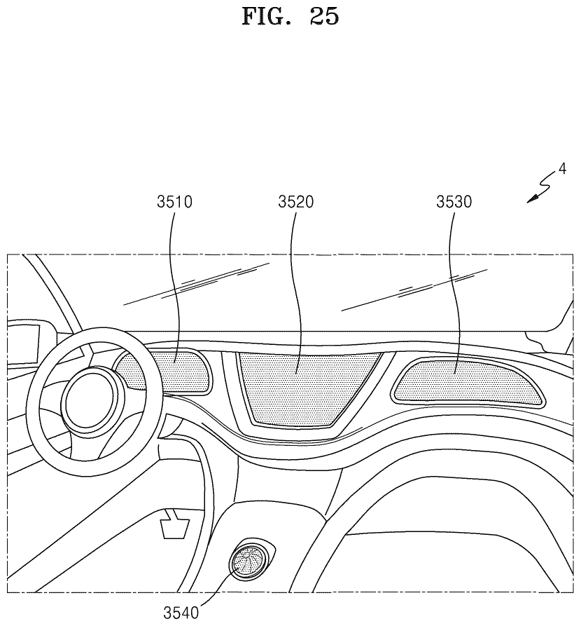

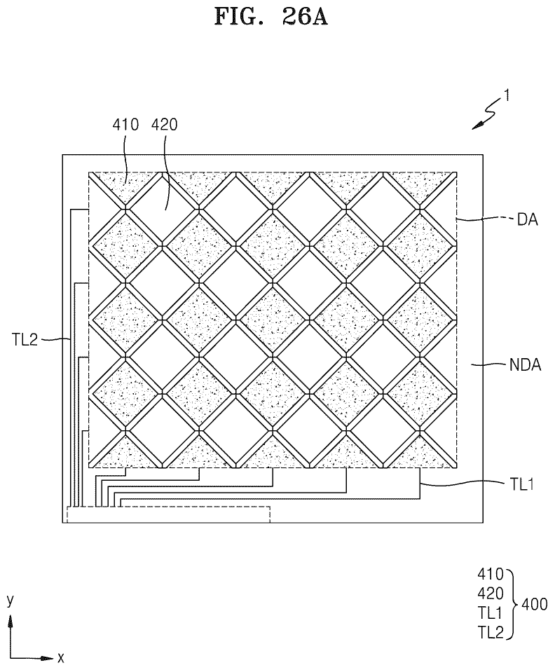

According to the embodiments described with reference to FIGS. 2A to 2E and 15, the display device 1 may be freely deformable three-dimensionally to provide an image plane capable of three-dimensional deformation, but one or more embodiments are not limited thereto. As shown in FIGS. 24 and 25, a display device may be arranged (or assembled) in a portion of an electronic product (or electronic device, electronic apparatus) where an image may be provided, and may be fixed to the electronic product while in a three-dimensionally deformed state.

FIGS. 24 and 25 are perspective views each showing an electronic product to which a display device has been applied, according to one or more embodiments.

FIG. 24 shows one or more embodiments in which a display device has been applied to a robot 3. The robot 3 may recognize a movement or object by using a camera 3440, and may display a corresponding image to the user through displays 3420 and 3430. A display device according to one or more embodiments may be three-dimensionally deformed as described above, and thus may be assembled into a hemispherical body frame, and accordingly, the robot 3 may include the displays 3420 and 3430 having a hemispherical shape. The displays 3420 and 3430 may sense a user's touch input.

FIG. 25 shows one or more embodiments in which a display device has been applied to a vehicular display device 4. The vehicular display device 4 may include a cluster 3510, a center information display (CID) 3520 and/or a co-driver display 3530.

A display device according to one or more embodiments may be three-dimensionally deformed, and thus may be used in the cluster 3510, the CID 3520, and/or the co-driver display 3530 regardless of a shape of an inner frame of a vehicle. The cluster 3510, the CID 3520 and/or the co-driver display 3530 may sense a touch input of a user (e.g., a driver).

Although FIG. 25 shows the cluster 3510, the CID 3520, and/or the co-driver display 3530, which are separated individually, one or more embodiments are not limited thereto. In one or more other embodiments, two or more selected from among the cluster 3510, the CID 3520, and the co-driver display 3530 may be integrally connected to each other.

In some embodiments, the automotive display device 4 may include a button 3540 capable of displaying a corresponding image. The button 3540 having a hemispherical shape may sense a touch input of a user (e.g., a driver) in a direction z or a direction −z.

As described with reference to FIGS. 24 and 25, when an image plane of a display device is fixed in a three-dimensionally deformed state, touch input sensing by a touch detector may be performed according to a method described below. In this case, the display device may not include a strain sensor and may include other elements, for example, a substrate, a display layer, a protection layer, and a touch layer. The substrate, the display layer, and the protection layer are the same as described above with reference to FIGS. 3 to 7D.

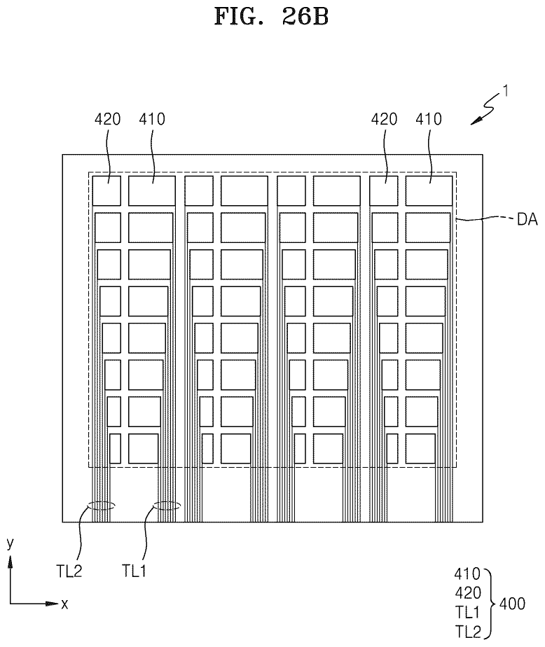

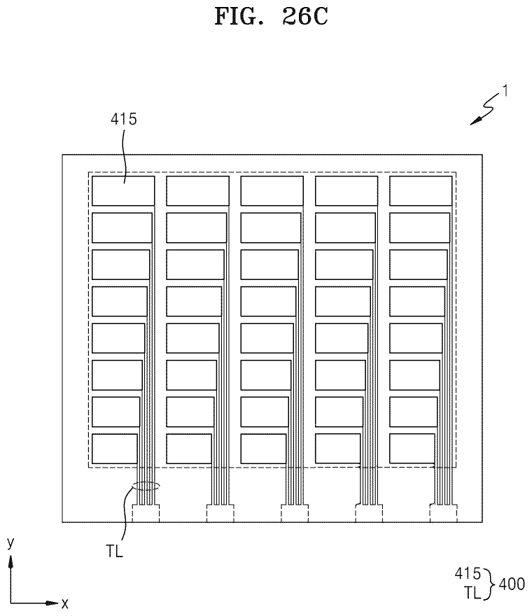

FIGS. 26A to 26C are plan views each showing touch electrodes of the display device 1 according to one or more embodiments. As described with reference to FIGS. 24 and 25, when an image plane of a display device is fixed in a three-dimensionally deformed state, the display device 1 may sense a touch input by using capacitance that is detected by a mutual capacitance method or a self-capacitance method. The touch detector of the display device 1 may detect capacitance of the touch electrode by using a mutual capacitance method or a self-capacitance method. In one or more embodiments, a touch layer of the display device 1 may include first and second touch electrodes 410 and 420 of a mutual capacitance type shown in FIG. 26A. In one or more other embodiments, a touch layer may include first and second touch electrodes 410 and 420 of a mutual capacitance type shown in FIG. 26B. In one or more other embodiments, a touch layer may include touch electrodes 415 of a self-capacitance type shown in FIG. 26C.

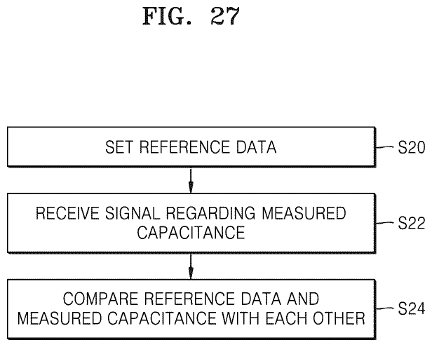

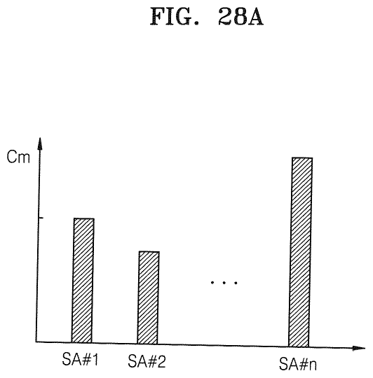

FIG. 27 is a flowchart showing operations of a touch detector according to

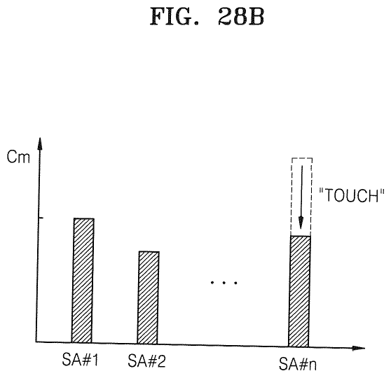

one or more embodiments. FIG. 28A is a graph for visually explaining reference data for each sub-area. FIG. 28B is a graph for visually explaining how a touch detector senses a touch input.

Referring to FIG. 27, the touch detector 450 (of FIG. 3) sets reference data (in step S20). In one or more embodiments, the touch detector 450 may set reference data based on a data setting command. The touch detector 450 may set reference data by receiving an elongation rate in each sub-area SA of the three-dimensionally deformed display device 1 (of FIG. 3) and by receiving capacitance of touch electrodes corresponding to each sub-area SA.

Capacitances of the sub-areas SA received by the touch detector 450 during a corresponding period (e.g., a reference data setting period) may be different for each other due to a shape of the display area DA of the three-dimensionally deformed display device 1. Because each sub-area SA has a different degree of elongation or contraction, a three-dimensional distance between touch electrodes varies, and accordingly, capacitance for each sub-area SA may vary. For example, capacitance of touch electrodes corresponding to a first sub-area SA #1, capacitance of touch electrodes corresponding to a second sub-area SA #2, and capacitance of touch electrodes corresponding to an n-th sub-area SA #n may be different from one another. FIG. 28A may correspond to reference data for each sub-area SA set based on capacitance collected during a corresponding period (e.g., a reference data setting period).

Referring to FIG. 27 again, after the reference data setting period, a user may apply a touch input to the display device 1 by using his or her body part, such as a finger. The display device 1 may receive a signal regarding each capacitance (hereinafter referred to as measured capacitance) of touch electrodes (in step S22).

The touch detector 450 may sense a touch input by comparing the measured capacitance with the reference data (in step S24). For example, when the measured capacitance at touch electrodes corresponding to any one sub-area, for example, the n-th sub-area SA #n, among the sub-areas SA shown in FIG. 28B deviates from the reference data, for example, a reference range on the graph, the touch detector 450 may sense that a touch input has occurred at a position corresponding to the corresponding sub-area, for example, the n-th sub-area SA #n.

According to one or more of the above embodiments, a display device that provides or is capable of providing a three-dimensional image plane may sense a touch input more suitably. However, such an aspect is an example, and one or more embodiments are not limited by the above aspect.

It should be understood that embodiments described herein should be considered in a descriptive sense only and not for purposes of limitation. Descriptions of aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a substrate;
light-emitting elements above the substrate, and defining a display area capable of providing a three-dimensional image plane;
a touch layer above the light-emitting elements, and comprising touch electrodes;
strain sensors in the display area; and
a touch detector electrically connected to the touch layer and to the strain sensors, and configured to sense a touch input based on a relationship between an elongation rate and capacitance of the display area.

2. The display device of claim 1, wherein the display area comprises sub-areas, and
wherein the strain sensors are in respective ones of the sub-areas.

3. The display device of claim 2, wherein the touch detector is configured to sense the touch input by comparing a measured elongation rate of the sub-areas and a measured capacitance of the touch electrodes corresponding to the sub-areas with reference data.

4. The display device of claim 3, wherein the touch detector is configured to generate the reference data by setting a relationship between an elongation rate of the sub-areas and a capacitance of the touch electrodes corresponding to the sub-areas according to three-dimensional deformation of the display area.

5. The display device of claim 3, wherein the touch electrodes comprise first touch electrodes arranged in a first direction and electrically connected to each other, and second touch electrodes arranged in a second direction crossing the first direction and electrically connected to each other.

6. The display device of claim 5, wherein each of the sub-areas correspond to a portion of two adjacent ones of the first touch electrodes and a portion of two adjacent ones of the second touch electrodes.

7. The display device of claim 3, wherein the touch electrodes comprise a column of first touch electrodes arranged in a first direction, and a column of second touch electrodes arranged in the first direction and adjacent to the column of the first touch electrodes in a second direction.

8. The display device of claim 3, wherein the touch electrodes comprise a column of first touch electrodes arranged in a first direction, and a second touch electrode adjacent to the column of the first touch electrodes in a second direction and extending in the first direction.

9. The display device of claim 1, wherein the strain sensors comprise a serpentine conductive line.

10. The display device of claim 9, wherein the display area comprises pixels corresponding to the light-emitting elements, and
wherein the serpentine conductive line has a mesh shape surrounding at least one of the pixels in plan view.

11. The display device of claim 1, further comprising a protection layer above the light-emitting elements, and
wherein the strain sensors are between the protection layer and the touch layer.

12. A display device comprising:
a substrate;
light-emitting elements above the substrate, and defining a display area capable of providing a three-dimensional image plane;
a touch layer above the light-emitting elements, and comprising touch electrodes;
strain sensors in a non-display area outside the display area; and
a touch detector electrically connected to the touch layer and the strain sensors, and configured to sense a touch input based on a relationship between an elongation rate and a capacitance of the display area.

13. The display device of claim 12, wherein the touch electrodes comprise an alternating arrangement of a column of first touch electrodes arranged in a first direction, and at least one second touch electrode adjacent to the column of the first touch electrodes in a second direction, and
wherein the strain sensors comprise a Wheatstone bridge comprising a corresponding one of the first touch electrodes.

14. The display device of claim 13, further comprising trace lines respectively connecting the strain sensors and the first touch electrodes, and passing through the display area.

15. The display device of claim 13, wherein the display area comprises sub-areas,
wherein the first touch electrodes are respectively arranged in the sub-areas, and
wherein the touch detector is configured to sense the touch input by comparing a measured elongation rate of the sub-areas and a measured capacitance of the touch electrodes corresponding to the sub-areas with reference data.

16. The display device of claim 15, wherein the touch detector is configured to generate the reference data by setting a relationship between an elongation rate of the sub-areas and a capacitance of the touch electrodes corresponding to the sub-areas according to three-dimensional deformation of the display area.

17. The display device of claim 12, wherein the touch electrodes are arranged in the first direction and the second direction,
wherein each of the strain sensors comprises a Wheatstone bridge comprising a corresponding one of the touch electrodes.

18. The display device of claim 17, further comprising trace lines respectively connecting the strain sensors and the touch electrodes, and passing through the display area.

19. The display device of claim 17, wherein the display area comprises sub-areas,
wherein the touch electrodes are respectively arranged in the sub-areas, and
wherein the touch detector is configured to sense the touch input by comparing a measured elongation rate of the sub-areas and a measured capacitance of the touch electrodes corresponding to the sub-areas with reference data.

20. The display device of claim 19, wherein the touch detector is configured to generate the reference data by setting a relationship between an elongation rate of the sub-areas and a capacitance of the touch electrodes corresponding to the sub-areas according to three-dimensional deformation of the display area.

21. A display device comprising:
a substrate;
light-emitting elements above the substrate, and defining a display area capable of providing a three-dimensional image plane and comprising sub-areas;
a touch layer above the light-emitting elements, and comprising touch electrodes; and
a touch detector electrically connected to the touch layer, and configured to sense a touch input by comparing capacitance of one of the touch electrodes corresponding to the sub-areas and reference data with each other.

22. The display device of claim 21, wherein the touch detector is configured to sense the capacitance by using a mutual capacitance method or a self-capacitance method.

23. An electronic product comprising a display device according to claim 1.

24. An electronic product comprising a display device according to claim 12.
